(19) United States
(12) Patent Application Publication
(10) Pub. No.: US 2024/0324311 A1
(43) Pub. Date: Sep. 26, 2024

(54) METHOD OF MANUFACTURING DISPLAY APPARATUS

(71) Applicant: Samsung Display Co., Ltd., Yongin-si (KR)

(72) Inventors: Israel Esteban Lazo Martinez, Yongin-si (KR); Yun Jang, Yongin-si (KR); Sukhoon Kang, Yongin-si (KR)

(21) Appl. No.: 18/590,202

(22) Filed: Feb. 28, 2024

(30) Foreign Application Priority Data
Mar. 24, 2023 (KR) 10-2023-0039184
May 2, 2023 (KR) 10-2023-0057349

(51) Int. Cl. H10K 59/122; H10K 59/12; H10K 59/38; H10K 71/40

(52) U.S. Cl. CPC H10K 59/122; H10K 59/1201; H10K 59/38; H10K 71/40

(57) ABSTRACT

A method of manufacturing a display apparatus includes supplying a substrate, forming a photoresist on the substrate, irradiating at least a portion of the photoresist with a pulse light including a plurality of pulses, and forming a bank layer by curing at least the portion of the photoresist irradiated with the pulse light, wherein a wavelength range of the pulse light is greater than or equal to about 250 nm and less than or equal to about 650 nm.

### CROSS-REFERENCE TO RELATED APPLICATIONS

This application claims priority to and the benefit of Korean Patent Application No. 10-2023-0039184, filed on Mar. 24, 2023, and Korean Patent Application No. 10-2023-0057349, filed on May 2, 2023, in the Korean Intellectual Property Office, the entire contents of which are both herein incorporated by reference.

### BACKGROUND

### 1. Field

One or more embodiments of the present disclosure relate to a method of manufacturing a display apparatus.

### 2. Description of Related Art

Display apparatuses may visually display data. A display apparatus may provide an image by using light emitting diodes. The uses of display apparatuses have diversified, and various designs have been attempted to improve the quality of display apparatuses.

### SUMMARY

Aspects of one or more embodiments of the present disclosure include a method of manufacturing a display apparatus.

Additional aspects will be set forth in part in the description which follows and, in part, will be apparent from the description, or may be learned by practice of the presented embodiments of the disclosure.

According to one or more embodiments of the present disclosure, a method of manufacturing a display apparatus includes supplying a substrate, forming a photoresist on the substrate, irradiating at least a portion of the photoresist with a pulse light including a plurality of pulses, and forming a bank layer by curing at least the portion of the photoresist irradiated with the pulse light, wherein a wavelength range of the pulse light is greater than or equal to about 250 nm to (and) less than or equal to about 650 nm.

According to the one or more embodiments, an intensity of the pulse light may be greater than or equal to about 1 kW/cm² to (and) less than or equal to about 50 kW/cm².

According to the one or more embodiments, a total energy of the pulse light may be about 20 J to about 200 J.

According to the one or more embodiments, a duration of at least one pulse of the plurality of pulses of the pulse light may be greater than or equal to about 500 μs to (and) less than or equal to about 5,000 μs.

According to the one or more embodiments, a curing rate of the bank layer may be greater than or equal to about 80% to (and) less than or equal to about 100%.

According to the one or more embodiments, a temperature of at least the portion of the photoresist irradiated with the pulse light may be greater than or equal to about 100° C. to (and) less than or equal to about 250° C.

According to the one or more embodiments, a temperature of the substrate may be greater than or equal to about 20° C. to (and) less than or equal to about 80° C. after (e.g., directly after) irradiating the portion of the photoresist with the pulse light.

According to the one or more embodiments, the method may further include pre-curing the photoresist before the irradiating of the portion of the photoresist with the pulse light.

According to the one or more embodiments, the method may further include removing a portion of the photoresist not irradiated with the pulse light before the forming of the bank layer by curing at least the portion of the photoresist irradiated with the pulse light.

According to the one or more embodiments, the photoresist may include a dye or a pigment.

According to the one or more embodiments, the photoresist may include carbon black or dichroic dye.

According to the one or more embodiments, the photoresist may include metal, dielectric, or oxide nanoparticles.

According to the one or more embodiments, the photoresist may include a radical photoinitiator.

According to the one or more embodiments, the photoresist may include an ultraviolet photoinitiator.

According to the one or more embodiments, the substrate may include at least one selected from among silicon oxynitride (SiON), silicon nitride (SiNₓ), silicon oxide (SiOₓ), polyimide, and/or polyethylene terephthalate (PET).

According to one or more embodiments of the present disclosure, a method of manufacturing a display apparatus includes supplying a substrate, forming a quantum dot-including material on the substrate, irradiating at least a portion of the quantum dot-including material with a pulse light including a plurality of pulses, and forming a color conversion layer by curing at least the portion of the quantum dot-including material irradiated with the pulse light, wherein the wavelength range of the pulse light is greater than or equal to about 250 nm to (and) less than or equal to about 650 nm.

According to the one or more embodiments, an intensity of the pulse light may be greater than or equal to about 1 kW/cm² to (and) less than or equal to about 50 kW/cm².

According to the one or more embodiments, a total energy of the pulse light may be greater than or equal to about 20 J to (and) less than or equal to about 200 J.

According to the one or more embodiments, a duration of at least one pulse of the plurality of pulses of the pulse light may be greater than or equal to about 500 μs to (and) less than or equal to about 5,000 μs.

According to the one or more embodiments, the quantum dot-including material may not include (e.g., may exclude) a pigment and/or a dye.

### BRIEF DESCRIPTION OF THE DRAWINGS

The above and other aspects, features, and/or privileges of certain embodiments of the disclosure will be more apparent from the following description taken in conjunction with the accompanying drawings, in which:

FIG. 1 is a perspective view schematically illustrating a display apparatus according to one or more embodiments of the present disclosure;

FIG. 2 is a cross-sectional view schematically illustrating pixels of a display apparatus according to one or more embodiments of the present disclosure;

FIG. 3 schematically illustrates optical units of the color conversion-transmission layer of FIG. 2, according to one or more embodiments of the present disclosure;

FIG. 4 is an equivalent circuit diagram illustrating a light emitting diode included in a display apparatus and a pixel circuit electrically connected to the light emitting diode, according to one or more embodiments of the present disclosure;

FIG. 5 schematically illustrates a cross-sectional view of the display apparatus of FIG. 1 taken along line I-I′, according to one or more embodiments of the present disclosure;

FIGS. 6-8 are each cross-sectional views schematically illustrating a method of manufacturing of a display apparatus, according to one or more embodiments of the present disclosure;

FIG. 9 is a table showing curing results of photoresists based on the types or kinds of light irradiation; and

FIGS. 10-12 schematically illustrate a method of manufacturing a display apparatus according to one or more embodiments of the present disclosure.

### DETAlLED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

The illustrated embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, duplicative descriptions thereof may not be provided.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an,” and “the” are intended to include the plural forms as well, unless the context clearly indicates otherwise.

Also, it will be understood that the terms “comprise,” “include,” and “have” used herein specify the presence of the stated features or elements, but do not preclude the presence or addition of one or more other features or elements.

It will be understood that when a layer, region, or component is referred to as being “on” another layer, region, or component, it may be “directly on” the other layer, region, or component or may be “indirectly on” the other layer, region, or component with one or more intervening layers, regions, or components therebetween. In addition, it will also be understood that when an element or layer is referred to as being “between” two elements or layers, it can be the only element or layer between the two elements or layers, or one or more intervening elements or layers may also be present.

Sizes of elements in the drawings may be exaggerated for convenience of description. In other words, because the sizes and shapes of components in the drawings may be arbitrarily illustrated for convenience of description, the present disclosure is not limited thereto.

When a certain embodiment may be implemented differently, a particular process order may be performed differently from the described order. For example, two processes described in succession may be performed substantially at the same time (concurrently) or may be performed in an order opposite to the described order.

As used herein, “A and/or B” represents the case of A, B, or A and B. Also, “at least one of A and B” represents the case of A, B, or A and B.

Spatially relative terms, such as “lower,” “under,” “over,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

The x axis, the y axis, and the z axis are not limited to three axes of the rectangular coordinate system and may be interpreted in a broader sense. For example, the x-axis, y-axis, and z-axis may be perpendicular to each other or may refer to different directions that are not perpendicular to each other.

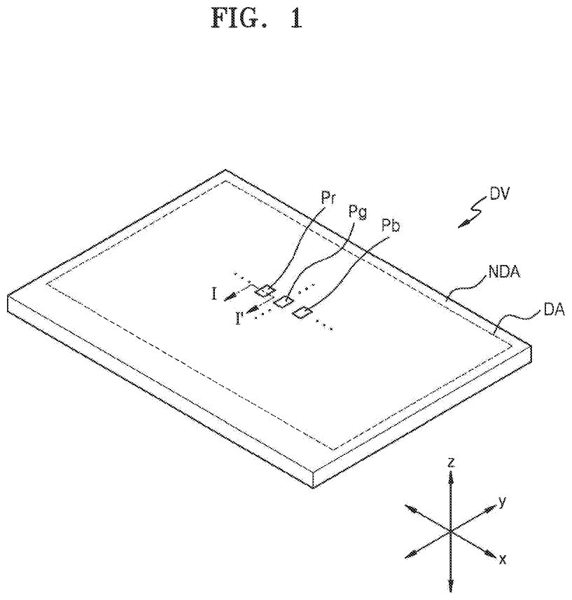

FIG. 1 is a perspective view schematically illustrating a display apparatus according to one or more embodiments of the present disclosure.

Referring to FIG. 1, a display apparatus DV may include a display area DA and a non-display area NDA outside the display area DA. The display apparatus DV may provide an image through an array of a plurality of pixels two-dimensionally arranged on the x-y plane in the display area DA. The plurality of pixels may include a first pixel, a second pixel, and a third pixel, and hereinafter, for convenience of description, an embodiment in which the first pixel is a red pixel Pr, the second pixel is a green pixel Pg, and the third pixel is a blue pixel Pb will be described.

The red pixel Pr, the green pixel Pg, and the blue pixel Pb may be areas capable of emitting red, green, and blue light, respectively, and the display apparatus DV may provide an image by using the light emitted from the pixels.

The non-display area NDA may be an area not providing an image and may be around (e.g., may entirely surround) the display area DA. A driver or a main voltage line for providing an electrical signal or power to the pixel circuits may be arranged in the non-display area NDA. The non-display area NDA may include a pad that is an area to which an electronic device or a printed circuit board may be electrically connected.

As illustrated in FIG. 1, the display area DA may have a polygonal shape including a tetragonal shape. For example, the display area DA may have a rectangular shape in which the horizontal length is greater than the vertical length, a rectangular shape in which the horizontal length is less than the vertical length, or a square shape. In one or more embodiments, the display area DA may have one or more suitable shapes, such as an elliptical shape or a circular shape.

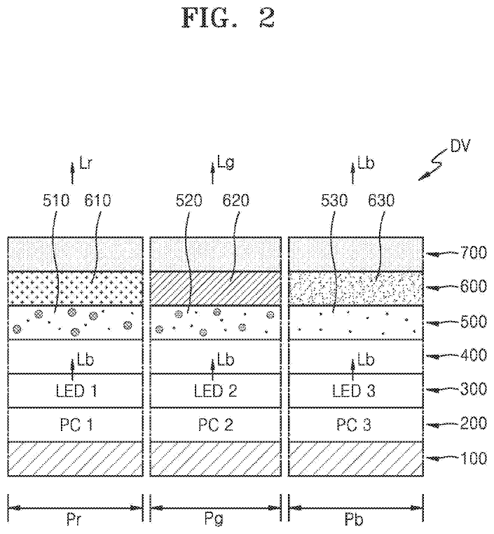

FIG. 2 is a cross-sectional view schematically illustrating each of pixels of a display apparatus according to one or more embodiments of the present disclosure.

Referring to FIG. 2, a display apparatus DV may include a circuit layer 200 over a first substrate 100. The circuit layer 200 may include first to third pixel circuits PC1, PC2, and PC3, and the first to third pixel circuits PC1, PC2, and PC3 may be respectively electrically connected to first to third light emitting diodes LED1, LED2, and LED3 of a light emitting diode layer 300.

The first to third light emitting diodes LED1, LED2, and LED3 may include an organic light emitting diode including an organic material. In one or more embodiments, the first to third light emitting diodes LED1, LED2, and LED3 may include an inorganic light emitting diode including an inorganic material. The inorganic light emitting diode may include a PN junction diode including inorganic semiconductor-based materials. If (e.g., when) a voltage is applied to the PN junction diode in a forward direction, holes and electrons may be injected thereinto and energy generated by recombination of the holes and electrons may be converted into light energy to emit light of a certain color. The inorganic light emitting diode may have a width of several to several hundred micrometers or several to several hundred nanometers. In one or more embodiments, a light emitting diode LED (e.g., light emitting diodes LED1, LED2, and LED3) may be a light emitting diode including quantum dots. As described above, an emission layer of the light emitting diode LED may include an organic material, may include an inorganic material, may include quantum dots, may include an organic material and quantum dots, or may include an inorganic material and quantum dots.

The first to third light emitting diodes LED1, LED2, and LED3 may emit light of the same (or substantially the same) color. For example, the light (e.g., blue light Lb) emitted from the first to third light emitting diodes LED1, LED2, and LED3 may pass through a color conversion-transmission layer 500 via an encapsulation layer 400 over the light emitting diode layer 300.

The color conversion-transmission layer 500 may include optical units that transmit the light (e.g., blue light Lb) emitted from the light emitting diode layer 300 with or without converting the color of the emitted light. For example, the color conversion-transmission layer 500 may include color conversion units 510, 520 that convert the light (e.g., blue light Lb) emitted from the light emitting diode layer 300 into light of another color and a transmission unit 530 that transmits the light (e.g., blue light Lb) emitted from the light emitting diode layer 300 without converting the color of the emitted light. The color conversion-transmission layer 500 may include a first color conversion unit 510 corresponding to the red pixel Pr, a second color conversion unit 520 corresponding to the green pixel Pg, and a transmission unit 530 corresponding to the blue pixel Pb. The first color conversion unit 510 may convert blue light Lb into red light Lr, and the second color conversion unit 520 may convert blue light Lb into green light Lg. The transmission unit 530 may transmit blue light Lb without conversion.

A color layer 600 may be disposed over the color conversion-transmission layer 500. The color layer 600 may include first to third color filters 610, 620, and 630 of different colors. For example, the first color filter 610 may be a red color filter, the second color filter 620 may be a green color filter, and the third color filter 630 may be a blue color filter.

The color purity of the color-converted light and the transmitted light by the color conversion-transmission layer 500 may be improved while passing through the first to third color filters 610, 620, and 630, respectively. Also, the color layer 600 may prevent, minimize, or reduce external light (e.g., light incident toward the display apparatus DV from the outside of the display apparatus DV) from being reflected and recognized by the user.

A second substrate 700 may be included over the color layer 600. The second substrate 700 may include glass or a transparent organic material. For example, the second substrate 700 may include a transparent organic material such as an acrylic resin.

In one or more embodiments, the color layer 600 and the color conversion-transmission layer 500 may be formed over the second substrate 700 and then integrated such that the color conversion-transmission layer 500 may face the encapsulation layer 400.

In one or more embodiments, the color conversion-transmission layer 500 and the color layer 600 may be sequentially formed on the encapsulation layer 400 and then the second substrate 700 may be directly applied and cured on the color layer 600. In one or more embodiments, another optical film such as an anti-reflection (AR) film may be disposed over the second substrate 700.

The display apparatus DV having the above structure may be included in a television, a billboard, a theater screen, a monitor, a tablet PC, a notebook computer, or the like.

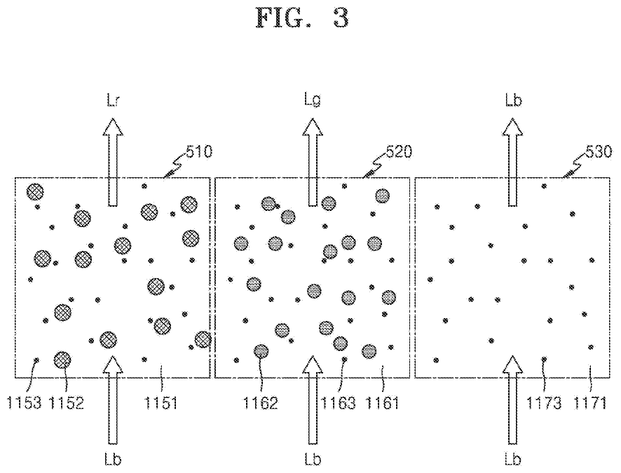

FIG. 3 schematically illustrates each of the optical units of the color conversion-transmission layer of FIG. 2, according to one or more embodiments of the present disclosure.

Referring to FIG. 3, the first color conversion unit 510 may convert incident blue light Lb into red light Lr. As illustrated in FIG. 3, the first color conversion unit 510 may include a first photosensitive polymer 1151, and first quantum dots 1152 and first scattering particles 1153 dispersed in the first photosensitive polymer 1151.

The first quantum dots 1152 may be excited by blue light Lb to isotropically emit red light Lr having a longer wavelength than the blue light Lb. The first photosensitive polymer 1151 may include an organic material having light transmittance. The first scattering particles 1153 may scatter blue light Lb, which has not been absorbed by the first quantum dots 1152, to excite more first quantum dots 1152, thereby increasing the color conversion efficiency. The first scattering particles 1153 may include, for example, titanium oxide (TiO₂), metal particles, and/or the like. The first quantum dots 1152 may include (e.g., may be selected from) a Group II-VI compound, a Group Ill-V compound, a Group IV-VI compound, a Group IV element, a Group IV compound, and/or any combination thereof.

The second color conversion unit 520 may convert incident blue light Lb into green light Lg. As illustrated in FIG. 3, the second color conversion unit 520 may include a second photosensitive polymer 1161 and second quantum dots 1162 and second scattering particles 1163 dispersed in the second photosensitive polymer 1161.

The second quantum dots 1162 may be excited by blue light Lb to isotropically emit green light Lg having a longer wavelength than the blue light Lb. The second photosensitive polymer 1161 may include an organic material having light transmittance.

The second scattering particles 1163 may scatter blue light Lb, which has not been absorbed by the second quantum dots 1162, to excite more second quantum dots 1162, thereby increasing the color conversion efficiency. The second scattering particles 1163 may include, for example, titanium oxide (TiO₂), metal particles, and/or the like. The second quantum dots 1162 may include (e.g., may be selected from) a Group II-VI compound, a Group Ill-V compound, a Group IV-VI compound, a Group IV element, a Group IV compound, and/or any combination thereof.

In one or more embodiments, the first quantum dots 1152 and the second quantum dots 1162 may be substantially the same material. In one or more embodiments, as shown for example in FIG. 3, the size of the first quantum dots 1152 may be greater than the size of the second quantum dots 1162.

The transmission unit 530 may transmit blue light Lb without converting blue light Lb incident on the transmission unit 530. As illustrated in FIG. 3, the transmission unit 530 may include a third photosensitive polymer 1171 in which third scattering particles 1173 are dispersed. The third photosensitive polymer 1171 may include, for example, an organic material having light transmittance, such as a silicon resin or an epoxy resin, and may include substantially the same material as the first and second photosensitive polymers 1151 and 1161. The third scattering particles 1173 may scatter and emit blue light Lb and may include substantially the same material as the first and second scattering particles 1153 and 1163.

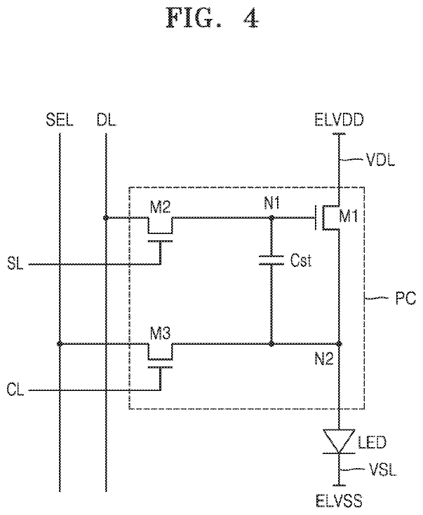

FIG. 4 is an equivalent circuit diagram illustrating a light emitting diode included in a display apparatus and a pixel circuit electrically connected to the light emitting diode, according to one or more embodiments of the present disclosure.

Referring to FIG. 4, a first electrode (e.g., an anode) of a light emitting diode, for example, a light emitting diode LED, may be connected to a pixel circuit PC, and a second electrode (e.g., cathode) of the light emitting diode LED may be connected to a common voltage line VSL for providing a common power voltage ELVSS. The light emitting diode LED may emit light with a luminance corresponding to the amount of a current supplied from the pixel circuit PC.

The light emitting diode LED of FIG. 4 may correspond to each or any of the first to third light emitting diodes LED1, LED2, and/or LED3 illustrated in FIG. 2, and the pixel circuit PC of FIG. 4 may correspond to each or any of the first to third pixel circuits PC1, PC2, and/or PC3 illustrated in FIG. 2.

The pixel circuit PC may control the amount of a current flowing from a driving power voltage ELVDD via the light emitting diode LED to the common power voltage ELVSS in response to a data signal. The pixel circuit PC may include a driving transistor M1, a switching transistor M2, a sensing transistor M3, and a storage capacitor Cst.

Each of the driving transistor M1, the switching transistor M2, and/or the sensing transistor M3 may be an oxide semiconductor thin film transistor including a semiconductor layer including an oxide semiconductor or may be a silicon semiconductor thin film transistor including a semiconductor layer including polysilicon. Each of the driving transistor M1, the switching transistor M2, and/or the sensing transistor M3 may include a source electrode (or source area) and a drain electrode (or drain area).

The source electrode (or source area) of the driving transistor M1 may be connected to a driving voltage line VDL for supplying the driving power voltage ELVDD, and the drain electrode (or drain area) of the driving transistor M1 may be connected to the first electrode (e.g., the anode) of the light emitting diode LED. The gate electrode of the driving transistor M1 may be connected to a first node N1. The driving transistor M1 may control the amount of a current flowing from the driving power voltage ELVDD through the light emitting diode LED in response to the voltage of the first node N1; however, the positions of the source electrode (or source area) and the drain electrode (or the drain area) may be modified.

The switching transistor M2 may be a switching transistor. The source electrode (or source area) of the switching transistor M2 may be connected to a data line DL, and the drain electrode (or drain area) of the switching transistor M2 may be connected to the first node N1. The gate electrode of the switching transistor M2 may be connected to a scan line SL. If (e.g., when) a scan signal is supplied to the scan line SL, the switching transistor M2 may be turned on to electrically connect the data line DL to the first node N1. However, the positions of the source electrode (or source area) and the drain electrode (or drain area) may be modified.

The sensing transistor M3 may be an initialization transistor and/or a sensing transistor. The drain electrode (or drain area) of the sensing transistor M3 may be connected to a second node N2, and the source electrode (or source area) of the sensing transistor M3 may be connected to a sensing line SEL. The gate electrode of the sensing transistor M3 may be connected to a control line CL. However, the positions of the source electrode (or source area) and the drain electrode (or drain area) may be modified.

The storage capacitor Cst may be connected between the first node N1 and the second node N2. For example, the first capacitor electrode of the storage capacitor Cst may be connected to the gate electrode of the driving transistor M1, and the second capacitor electrode of the storage capacitor Cst may be connected to the first electrode (e.g., the anode) of the light emitting diode LED.

In FIG. 4, the driving transistor M1, the switching transistor M2, and the sensing transistor M3 are illustrated as NMOS transistors; however, the present disclosure is not limited thereto. For example, at least one of the driving transistor M1, the switching transistor M2, and/or the sensing transistor M3 may be formed as a PMOS transistor.

Although three transistors are illustrated in FIG. 4, the present disclosure is not limited thereto. The pixel circuit PC may include four or more transistors.

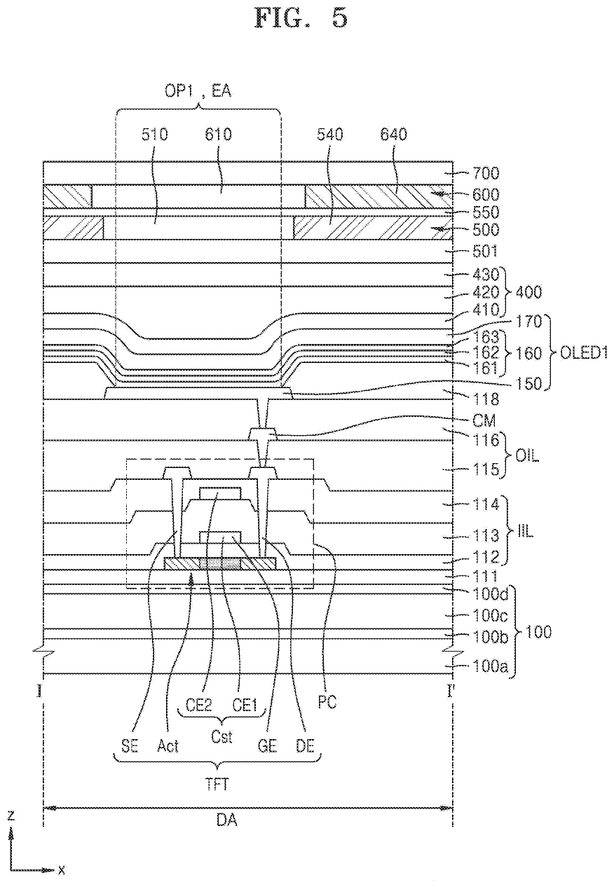

FIG. 5 schematically illustrates a cross-sectional view of a display apparatus according to one or more embodiments of the present disclosure. Particularly, FIG. 5 schematically illustrates a cross-sectional view of the display apparatus of FIG. 1 taken along line I-I′, according to one or more embodiments of the present disclosure.

Referring to FIG. 5, the display apparatus DV may include a first substrate 100, an inorganic insulating layer IIL, an organic insulating layer OIL, a pixel circuit PC, a connection electrode CM, a first organic light emitting diode OLED1, a pixel definition layer 118, an encapsulation layer 400, a color conversion-transmission layer 500, a color layer 600, and a second substrate 700.

The first substrate 100 may include a first base layer 100a, a first barrier layer 100b, a second base layer 100c, and a second barrier layer 100d. In one or more embodiments, the first base layer 100a, the first barrier layer 100b, the second base layer 100c, and the second barrier layer 100d may be sequentially stacked in the thickness direction of the first substrate 100.

At least one of the first base layer 100a and/or the second base layer 100c may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The first barrier layer 100b and the second barrier layer 100d may be barrier layers for preventing or substantially preventing penetration of external foreign substances and may include a single layer or multiple layers including an inorganic material such as silicon nitride (SiNₓ), silicon oxide (SiO₂), and/or silicon oxynitride (SiON).

A buffer layer 111 may be disposed over the first substrate 100. The buffer layer 111 may include an inorganic insulating material such as silicon nitride (SiNₓ), silicon oxynitride (SiON), and/or silicon oxide (SiO₂) and may include a single layer or multiple layers including the inorganic insulating material(s).

The inorganic insulating layer IIL may be disposed over the buffer layer 111. The inorganic insulating layer IIL may include a first gate insulating layer 112, a second gate insulating layer 113, and an interlayer insulating layer 114.

The pixel circuit PC may be arranged in the display area DA. The pixel circuit PC may include a thin film transistor TFT and a storage capacitor Cst. The thin film transistor TFT may include a semiconductor layer Act, a gate electrode GE, a source electrode SE, and a drain electrode DE.

The semiconductor layer Act may be disposed over the buffer layer 111. The semiconductor layer Act may include polysilicon. In one or more embodiments, the semiconductor layer Act may include amorphous silicon, may include an oxide semiconductor, or may include an organic semiconductor or the like. The semiconductor layer Act may include a channel area, and a drain area and a source area respectively arranged on both (e.g., opposite) sides of the channel area.

The gate electrode GE may be disposed over the semiconductor layer Act. The gate electrode GE may overlap the channel area. The gate electrode GE may include a low-resistance metal material. The gate electrode GE may include a conductive material including molybdenum (Mo), aluminum (Al), copper (Cu), titanium (Ti), and/or the like and may include a single layer or multiple layers including the above material(s).

The first gate insulating layer 112 may be arranged between the semiconductor layer ACT and the gate electrode GE. The first gate insulating layer 112 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The second gate insulating layer 113 may be disposed over the gate electrode GE. The second gate insulating layer 113 may be provided to cover the gate electrode GE. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

An upper electrode CE2 of the storage capacitor Cst may be disposed over the second gate insulating layer 113. The upper electrode CE2 may overlap the gate electrode GE disposed thereunder. In one or more embodiments, as shown, for example in FIG. 5, the gate electrode GE and the upper electrode CE2 overlapping each other with the second gate insulating layer 113 therebetween may form the storage capacitor Cst. That is, the gate electrode GE may function as a lower electrode CE1 of the storage capacitor Cst.

As such, the storage capacitor Cst and the thin film transistor TFT may be formed to overlap each other. However, the present disclosure is not limited thereto. For example, the storage capacitor Cst may be formed not to overlap the thin film transistor TFT. That is, the lower electrode CE1 of the storage capacitor Cst may be provided apart from (e.g., separate from) the gate electrode GE of the thin film transistor TFT as a separate component from the gate electrode GE of the thin film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single layer or multiple layers of the above material.

The interlayer insulating layer 114 may be disposed over the upper electrode CE2. The interlayer insulating layer 114 may cover the upper electrode CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO). The interlayer insulating layer 114 may include a single layer or multiple layers including the above inorganic insulating material(s).

Each of the drain electrode DE and the source electrode SE may be located over the interlayer insulating layer 114. Each of the drain electrode DE and the source electrode SE may be connected to the semiconductor layer Act through a contact hole included in the first gate insulating layer 112, the second gate insulating layer 113, and the interlayer insulating layer 114. The drain electrode DE and the source electrode SE may include a material having high conductivity. The drain electrode DE and the source electrode SE may include a conductive material including molybdenum (Mo), aluminum (Al), copper (Cu), titanium (Ti), and/or the like and may include a single layer or multiple layers including the above material(s). For example, the drain electrode DE and the source electrode SE may have a multilayer structure of Ti/Al/Ti.

The organic insulating layer OIL may be disposed over the inorganic insulating layer IIL. The organic insulating layer OIL may include a first organic insulating layer 115 and a second organic insulating layer 116. FIG. 5 illustrates that the organic insulating layer OIL includes two organic insulating layers; however, the present disclosure is not limited thereto. The organic insulating layers OIL may include three or four organic insulating layers.

The first organic insulating layer 115 may cover the drain electrode DE and the source electrode SE. The first organic insulating layer 115 may include an organic insulating material such as a general-purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymers, a p-xylene-based polymer, a vinyl alcohol-based polymer, or any blend thereof.

The connection electrode CM may be disposed over the first organic insulating layer 115. In one or more embodiments, as shown, for example, in FIG. 5, the connection electrode CM may be connected to the drain electrode DE or the source electrode SE through a contact hole of (in) the first organic insulating layer 115. The connection electrode CM may include a high-conductivity material. The connection electrode CM may include a conductive material including molybdenum (Mo), aluminum (Al), copper (Cu), titanium (Ti), and/or the like and may include a single layer or multiple layers including the above material(s). For example, the connection electrode CM may include a multilayer structure of Ti/Al/Ti.

The second organic insulating layer 116 may be disposed over the connection electrode CM. The second organic insulating layer 116 may cover the connection electrode CM. The second organic insulating layer 116 may include substantially the same material as the first organic insulating layer 115 or may include a different material than the first organic insulating layer 115.

A first electrode 150 of a light emitting diode may be disposed over the second organic insulating layer 116. For example, FIG. 5 illustrates the first electrode 150 of the first organic light emitting diode OLED1. In this embodiment, the first electrode 150 may be an anode.

The first electrode 150 may be connected to the pixel circuit PC through the connection electrode CM connected through a contact hole defined in the second organic insulating layer 116.

The first electrode 150 may include a transparent conductive oxide such as indium tin oxide (ITO), indium zinc oxide (IZO), zinc oxide (ZnO), indium oxide (In₂O₃), indium gallium oxide (IGO), or aluminum zinc oxide (AZO). In one or more embodiments, the first electrode 150 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In one or more embodiments, the first electrode 150 may further include a layer formed of ITO, IZO, ZnO, or In₂O₃ over/under the above reflective layer. For example, the first electrode 150 may have a three-layer structure in which an ITO layer, a silver (Ag) layer, and an ITO layer are stacked.

The pixel definition layer 118 may cover an edge of the first electrode 150 and may include a first opening OP1 overlapping a center portion of the first electrode 150 (or exposing at least a portion of the first electrode 150). The pixel definition layer 118 may include an organic insulating material such as a polyimide.

An intermediate layer 160 may contact the first electrode 150 through the first opening OP1 of the pixel definition layer 118. A stack structure of the first electrode 150, the intermediate layer 160, and a second electrode 170 located in the first opening OP1 may emit light of a certain color. The first opening OP1 of the pixel definition layer 118 may correspond to an emission area EA through which light is emitted. For example, the size (or width) of the first opening OP1 of the pixel definition layer 118 may correspond to the size (or width) of the emission area EA.

The intermediate layer 160 may include an emission layer 162. The emission layer 162 may include a high-molecular or low-molecular weight organic material for emitting light of a certain color. As described above with reference to FIG. 2, if (e.g., when) the light emitting diode layer 300 (see, e.g., FIG. 2) emits blue light, the emission layer 162 may include a high molecular or low molecular weight organic material for emitting blue light.

In one or more embodiments, the intermediate layer 160 may include at least one functional layer located over or under the emission layer 162. For example, as illustrated in FIG. 5, the intermediate layer 160 may include a first functional layer 161 disposed under the emission layer 162 and/or a second functional layer 163 disposed over the emission layer 162. The first functional layer 161 may be arranged between the first electrode 150 and the emission layer 162, and the second functional layer 163 may be arranged between the emission layer 162 and the second electrode 170 described below.

The first functional layer 161 may include a hole transport layer (HTL) and/or a hole injection layer (HIL). The second functional layer 163 may include an electron transport layer (ETL) and/or an electron injection layer (EIL).

The second electrode 170 may be disposed over the intermediate layer 160. The second electrode 170 may be, for example, a cathode. The second electrode 170 may include a conductive material having a low work function. For example, the second electrode 170 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any suitable alloy thereof. In one or more embodiments, the second electrode 170 may further include a layer such as ITO, IZO, ZnO, or In₂O₃ over the (semi)transparent layer including the above material(s).

In one or more embodiments, the encapsulation layer 400 may be disposed over the second electrode 170. The encapsulation layer 400 may include at least one inorganic encapsulation layer and at least one organic encapsulation layer. In one or more embodiments, the encapsulation layer 400 may include a first inorganic encapsulation layer 410, an organic encapsulation layer 420, and a second inorganic encapsulation layer 430. The organic encapsulation layer 420 may be arranged between the first inorganic encapsulation layer 410 and the second inorganic encapsulation layer 430.

Each of the first and second inorganic encapsulation layers 410 and 430 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The organic encapsulation layer 420 may include a polymer-based material. The polymer-based material may include acryl-based resin, epoxy-based resin, polyimide, polyethylene, and/or the like. For example, the organic encapsulation layer 420 may include acryl-based resin such as polymethylmethacrylate or polyacrylic acid. The organic encapsulation layer 420 may be formed by curing a monomer or applying a polymer.

An intermediate material layer 501 may be disposed over the encapsulation layer 400. The intermediate material layer 501 may include an inorganic insulating material and/or an organic insulating material. The color conversion-transmission layer 500 may be located over the intermediate material layer 501. For example, FIG. 5 illustrates a bank layer 540 of the color conversion-transmission layer 500 and a first color conversion unit 510 located in an opening area defined by the bank layer 540.

A barrier layer 550 may be formed over the color conversion-transmission layer 500. The barrier layer 550 may include an inorganic insulating material such as silicon oxide, silicon nitride, and/or silicon oxynitride.

The color layer 600 may be disposed over the color conversion-transmission layer 500. For example, FIG. 5 illustrates a second bank layer 640 of the color layer 600 and a first color filter 610 located in an opening area defined by the bank layer 640. The bank layer 540 (hereinafter, referred to as a first bank layer 540) of the color conversion-transmission layer 500 and the bank layer 640 (hereinafter, referred to as a second bank layer 640) of the color layer 600 may be arranged to overlap each other.

Each of the first bank layer 540 and the second bank layer 640 may include a light blocking material. For example, the first bank layer 540 and the second bank layer 640 may include dye and/or pigment. Each of the first bank layer 540 and the second bank layer 640 may include an organic material having a certain color such as black. For example, the first bank layer 540 and the second bank layer 640 may include carbon black or dichroic dye. However, the present disclosure is not limited thereto.

In one or more embodiments, the first bank layer 540 and the second bank layer 640 may include substantially the same material. In one or more embodiments, the second bank layer 640 may have a structure in which at least two or more color filters forming the color layer 600 overlap each other. For example, the second bank layer 640 may not include (e.g., may exclude) the above light blocking material and may have a structure in which two or more color filter materials of (e.g., selected from among) the first to third color filters 610, 620, and/or 630 (see, e.g., FIG. 2) are stacked.

The second substrate 700 may include glass or a transparent organic material. For example, the second substrate 700 may include a transparent organic material such as an acrylic resin.

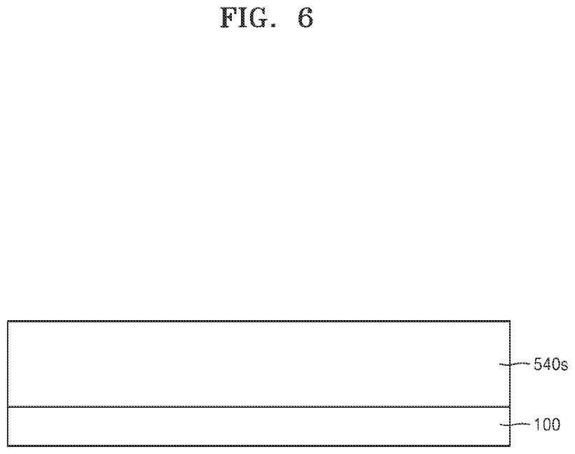

FIGS. 6 to 8 are cross-sectional views schematically illustrating a method of manufacturing of a display apparatus, according to one or more embodiments of the present disclosure. Particularly, FIGS. 6 to 8 are cross-sectional views schematically illustrating a method of manufacturing a first bank layer 540 or a second bank layer 640 of a display apparatus.

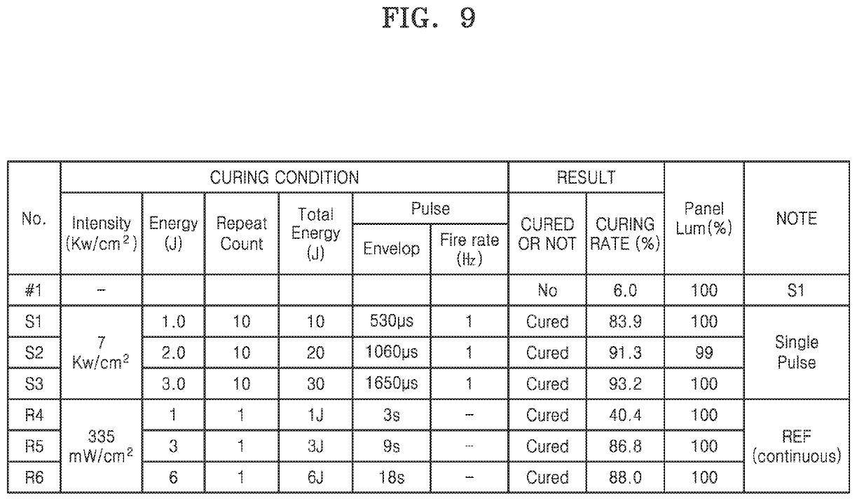

FIG. 9 is a table schematically illustrating curing results of photoresists based on the types or kinds of light irradiation. A method of manufacturing a display apparatus will be described with reference to FIGS. 6 to 8 together with the table of FIG. 9.

Referring to FIG. 6, a photoresist 540s may be formed over a first substrate 100. In one or more embodiments, an intermediate layer 160 or the like may be arranged between the first substrate 100 and the photoresist 540s. However, the present disclosure is not limited thereto.

In one or more embodiments, the photoresist 540s may include an acryl or epoxy-based monomer. The photoresist 540s may include a thermocurable binder. The thermocurable binder may be bonded to an acryl or epoxy-based monomer for bonding force and solidity of the photoresist 540s. The photoresist 540s may include a solvent such as propylene glycol methyl ether acetate (PGMEA). The photoresist 540s may include particles capable of absorbing visible light. For example, the photoresist 540s may include dye and/or pigment. For example, the photoresist 540s may include carbon black or dichroic dye. The photoresist 540s may include metal, dielectric, or oxide nanoparticles as particles absorbing visible light. For example, the photoresist 540s may include copper or silver nanoparticles. Also, the photoresist 540s may include a radical photoinitiator. The radical photoinitiator may generate free radicals if (e.g., when) irradiated with light, and the generated free radicals may cause polymerization of the photoresist 540s. The photoresist 540s may include a radical photoinitiator such as UV-Irgacure (UV photoinitiator). The UV-Irgacure (UV photoinitiator) may generate free radicals if (e.g., when) irradiated with ultraviolet (UV), and the generated free radicals may cause polymerization of the photoresist 540s.

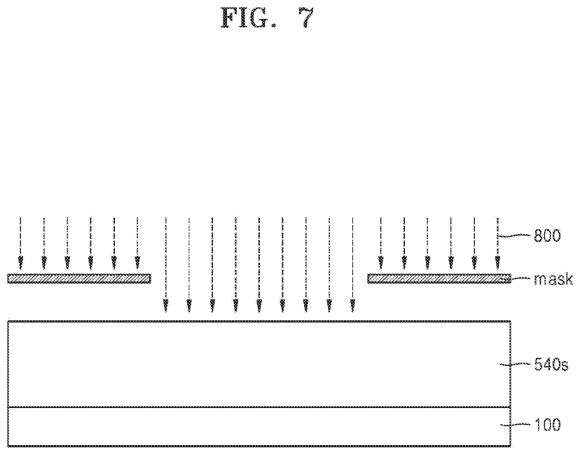

Referring to FIG. 7, a mask may be disposed over the photoresist 540s. For example, a photomask may be disposed over the photoresist 540s. Pulse light 800 including a plurality of pulses may be irradiated to the photoresist 540s. For example, the pulse light 800 may be irradiated onto at least a portion of the photoresist 540s. At least a portion of the photoresist 540s irradiated with the pulse light 800 may be cured to form a bank layer (e.g., the first or second bank layer 540, 640). The photoresist 540s may be pre-cured before the irradiating of the pulse light 800 onto at least a portion of the photoresist 540s. If (e.g., when) the photoresist 540s is pre-cured, the temperature of the photoresist 540s may be about 80° C. to about 100° C.

The pulse light 800 may include ultraviolet light and visible light. For example, the wavelength range of the pulse light 800 may be about 250 nm to about 650 nm including ultraviolet light and visible light. In one or more embodiments, the wavelength range of the pulse light 800 may be about 250 nm to about 700 nm including ultraviolet light and visible light. In one or more embodiments, the wavelength range of the pulse light 800 may be about 250 nm to about 750 nm including ultraviolet light and visible light. Also, the wavelength range of the pulse light 800 may be about 250 nm to about 800 nm including ultraviolet light and visible light. However, the present disclosure is not limited thereto.

The radical photoinitiator such as UV-Irgacure (UV photoinitiator) included in the photoresist 540s may absorb UV (ultraviolet light). The radical photoinitiator such as UV-Irgacure (UV photoinitiator) having absorbed ultraviolet light may generate free radicals to trigger polymerization of the photoresist 540s.

The carbon black or dichroic dye included in the photoresist 540s may absorb visible light. The carbon black or dichroic dye included in the photoresist 540s may absorb light in the visible light band. The carbon black or dichroic dye included in the photoresist 540s may absorb visible light and then transmit energy in the form of heat to the surroundings thereof. The photoresist 540s may be cured as the carbon black or dichroic dye included in the photoresist 540s transmits heat to the surroundings thereof. For example, as the carbon black or dichroic dye included in the photoresist 540s transmits heat to the surroundings thereof, the solvent of the photoresist 540s may be evaporated or acryl or epoxy-based monomers may be bonded each other.

The metal, dielectric, or oxide nanoparticles included in the photoresist 540s may absorb visible light. The metal nanoparticles included in the photoresist 540s may be silver or copper nanoparticles. The metal, dielectric, or oxide nanoparticles included in the photoresist 540s may absorb light in the visible light band. The metal, dielectric, or oxide nanoparticles included in the photoresist 540s may absorb visible light and then transmit energy in the form of heat to the surroundings thereof. The photoresist 540s may be cured as the metal, dielectric, or oxide nanoparticles included in the photoresist 540s transmit heat to the surroundings thereof. For example, as the carbon black or dichroic dye included in the photoresist 540s transmits heat to the surroundings thereof, the solvent of the photoresist 540s may be evaporated or acryl or epoxy-based monomers may be bonded each other.

Because the carbon black, dichroic dye, or metal, dielectric, or oxide nanoparticles included in the photoresist 540s absorb visible light and emit heat to the surroundings thereof, the temperature of at least a portion of the photoresist 540s irradiated with the pulse light 800 including visible light may increase. After the pulse light 800 irradiates the photoresist 540s, the temperature of the photoresist 540s may be about 100° C. to about 250° C. The temperature of at least a portion of the photoresist 540s irradiated with the pulse light 800 may be about 100° C. to about 250° C. In one or more embodiments, the temperature of at least a portion of the photoresist 540s irradiated with the pulse light 800 may be about 100° C. to about 300° C. In one or more embodiments, the temperature of at least a portion of the photoresist 540s irradiated with the pulse light 800 may be about 100° C. to about 350° C.

The temperature of the photoresist 540s irradiated with the pulse light 800 increases because the carbon black, dichroic dye, or metal, dielectric, or oxide nanoparticles included in the photoresist 540s absorb visible light and emit heat to the surroundings thereof, and therefore, the temperature of only at least a portion of the photoresist 540s irradiated with the pulse light 800 may increase locally. Also, the first substrate 100 may include a material with low thermal conductivity. The first substrate 100 may include silicon oxynitride (SiON), silicon nitride (SiNₓ), silicon oxide (SiOₓ), polyimide, or polyethylene terephthalate (PET). The temperature of the first substrate 100 including a material with low thermal conductivity may not increase. After at least a portion of the photoresist 540s is irradiated with the pulse light 800 (e.g., directly after at least the portion of the photoresist 540s is irradiated with the pulse light 800), the temperature of the first substrate 100 may be about 20° C. to about 80° C. In other words, if (e.g., when) the photoresist 540s is cured by irradiating at least a portion of the photoresist 540s with the pulse light 800 including visible light and ultraviolet light, the temperature of the first substrate 100 disposed under the photoresist 540s may be maintained without increase.

Referring to FIG. 9, S1, S2, and S3 represent curing conditions and result values when the photoresist 540s was cured by being irradiated with the pulse light 800 including a plurality of pulses. R4, R5, and R6 represent curing conditions and result values when the photoresist 540s was cured by being continuously irradiated with light. The total intensity of the pulse light 800 may be 7 kW/cm² and may be greater than 335 mW/cm², which is the intensity of light when the light continuously irradiates. However, in S1, when the pulse light 800 irradiated the photoresist 540s, the duration of at least one pulse included in the pulse light 800 was about 530 μs, and because the pulse irradiated 10 times, the total duration of the pulse light 800 was about 5300 μs. In contrast, in R4, when light continuously irradiated the photoresist 540s, the light irradiation time was about 3 seconds longer than when the pulse light 800 irradiated the photoresist 540s. Comparing the curing rates of the first bank layer 540 formed by curing the photoresist 540s, the curing rate of the first bank layer 540 reached about 84% when the pulse light 800 irradiated the photoresist 540s in S1, whereas the curing rate of the first bank layer 540 was about 40% when light continuously irradiated the photoresist 540s. When the pulse light 800 irradiates the photoresist 540s, the curing rate of the bank layers 540 and 640 may be improved in a shorter time than if (e.g., when) light continuously irradiates the photoresist 540s. If (e.g., when) the pulse light 800 irradiates the photoresist 540s, the process efficiency may increase relative to when light continuously irradiates the photoresist 540s.

In one or more embodiments, the intensity of the pulse light 800 may be about 1 kW/cm² to about 50 kW/cm². If (e.g., when) the intensity of the pulse light 800 is less than 1 kW/cm², it may not be sufficient for polymerization of the photoresist 540s and curing of the photoresist 540s. Also, if (e.g., when) the intensity of the pulse light 800 exceeds 50 kW/cm², the photoresist 540s may be damaged. Also, if (e.g., when) the intensity of the pulse light 800 exceeds 50 kW/cm², damage may be applied to the first substrate 100 or the intermediate layer 160 disposed under the photoresist 540s. The total energy of the pulse light 800 may be about 20 J to about 200 J. If (e.g., when) the total energy of the pulse light 800 is less than 20 J, it may not be sufficient for polymerization of the photoresist 540s and curing of the photoresist 540s. Also, if (e.g., when) the total energy of the pulse light 800 exceeds 200 J, the photoresist 540s may be damaged. Also, if (e.g., when) the total energy of the pulse light 800 exceeds 200 J, damage may be applied to the first substrate 100 or the intermediate layer 160 disposed under the photoresist 540s. The duration of at least one pulse included in the pulse light 800 may be about 500 μs to about 5,000 μs. If (e.g., when) the duration of at least one pulse included in the pulse light 800 is less than 500 μs, the energy of one pulse should be high, and if (e.g., when) the pulse light with high energy irradiates for a short time, damage may be applied to the first substrate 100 or the intermediate layer 160 disposed under the photoresist 540s. If (e.g., when) the duration of at least one pulse included in the pulse light 800 exceeds 5,000 μs, the time required for the process may become similar and thus the process efficiency may not increase compared to the existing process of continuously irradiating light. Also, the duration of the pulse light 800 may increase and thus the temperature of the first substrate 100 may increase.

In the related art, after a photoresist disposed over a first substrate is cured, the photoresist is subsequently heat-treated in an oven to form a bank layer. If (e.g., when) the first substrate and the photoresist disposed over the first substrate are arranged in the oven and subsequently heat-treated (a post-bake process), the temperature of the first substrate as well as the photoresist may increase to about 250° C. and accordingly, the first substrate and the intermediate layer may be damaged. Also, the time required to subsequently heat-treat the first substrate and the photoresist disposed over the first substrate in the oven (a post-bake process) may be about 30 minutes to about 60 minutes, which may be a relatively long time.

In one or more embodiments, because at least a portion of the photoresist 540s may be irradiated with the pulse light 800 including visible light and ultraviolet light and thus the temperature of the photoresist 540s may increase due to the heat emitted by the carbon black or dichroic dye of the photoresist 540s having absorbed visible light, the temperature of only at least a portion of the photoresist 540s irradiated with the pulse light 800 may increase locally and damage to the first substrate 100 and the intermediate layer 160 disposed under the photoresist 540s may be prevented or reduced. Also, because the temperature of at least a portion of the photoresist irradiated with the pulse light may increase to about 250° C., a subsequent heat treatment process may not be required and if (e.g., when) the pulse light 800 irradiates the photoresist, because the pulse light 800 irradiates for a short time of about milliseconds, the time required for the process may decrease and thus the process efficiency may increase, compared to the case of curing by continuously irradiating light or the case of performing a subsequent heat treatment (a post-bake process) in the oven. Also, if (e.g., when) the pulse light 800 with high intensity irradiates the photoresist 540s, the pulse light 800 may reach the photoresist 540s adjacent to the substrate, compared to the case where the photoresist 540s is cured through a curing machine. Thus, if (e.g., when) the photoresist 540s is cured by irradiating it with the pulse light 800, the hardness of the first bank layer 540 may be improved and the inclination angle (taper angle) between the bank layers 540 and 640 and the first substrate 100 may be freely formed in a wide range. For example, the bank layers 540 and 640 are formed in a rectangular shape, or the bank layers 540 and 640 may have a trapezoidal shape in which the edge thereof contacting the first substrate 100 is longer than the edge thereof spaced apart from (separated from) the first substrate 100. If (e.g., when) the photoresist 540s is cured by irradiating it with the pulse light 800, a generally utilized/generally available material may be utilized for development (e.g., removal of the portions of the photoresist 540s not cured by irradiation) and by-products may not remain after the development, compared to the case of using the photoresist 540s whose temperature increases to about 100° C.

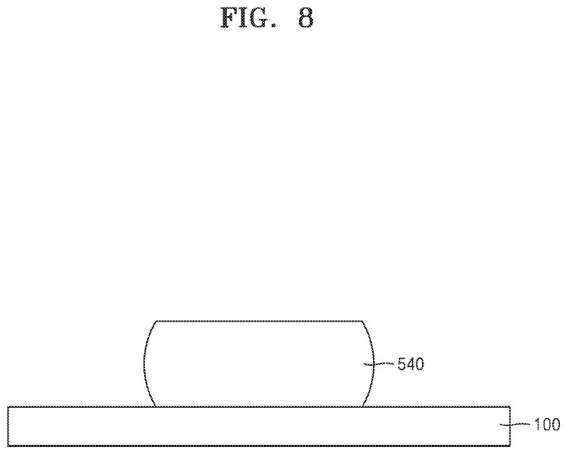

Referring to FIG. 8, a portion of the photoresist 540s not irradiated with the pulse light 800 may be developed (e.g., removed). At least a portion of the photoresist 540s irradiated with the pulse light 800 may be cured to form a bank layer (540, 640). The curing rate of the bank layers 540 and 640 may be about 80% to about 100%. If (e.g., when) the bank layers 540 and 640 are formed by irradiating the pulse light 800 onto at least a portion of the photoresist 540s, the inclination angle (taper angle) between the first bank layer 540 and the first substrate 100 may vary. In one or more embodiments, the bank layers 540 and 640 may have a rectangular shape. Also, the bank layers 540 and 640 may have a trapezoidal shape in which the edge thereof contacting the first substrate 100 is longer than the edge thereof spaced apart from (separated from) the first substrate 100.

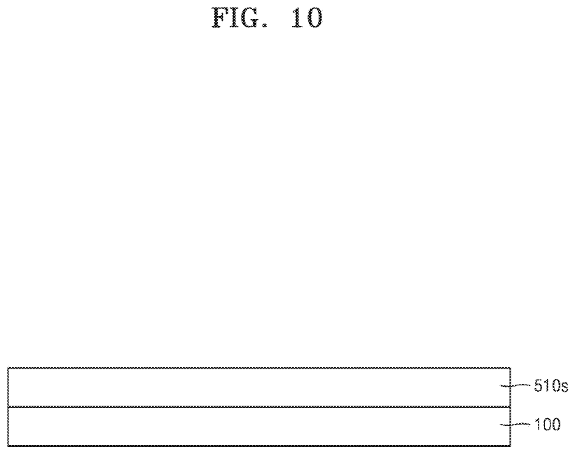

FIG. 10 to 12 schematically illustrate a method of manufacturing a display apparatus according to one or more embodiments of the present disclosure. Particularly, FIGS. 10 to 12 schematically illustrate an operation of forming a color conversion layer 510 or an emission layer 162 by curing a quantum dot-including material 510s on a first substrate 100.

Referring to FIG. 10, a quantum dot-including material 510s may be formed over the first substrate 100. The quantum dot-including material 510s may include a radical photoinitiator in addition to quantum dots. The radical photoinitiator may generate free radicals if (e.g., when) irradiated with light, and the generated free radicals may cause polymerization of the quantum dot-including material 510s. The quantum dot-including material 510s may include a radical photoinitiator such as UV-Irgacure (UV photoinitiator). The UV-Irgacure (UV photoinitiator) may generate free radicals if (e.g., when) irradiated with ultraviolet (UV), and the generated free radicals may cause polymerization of the quantum dot-including material 510s.

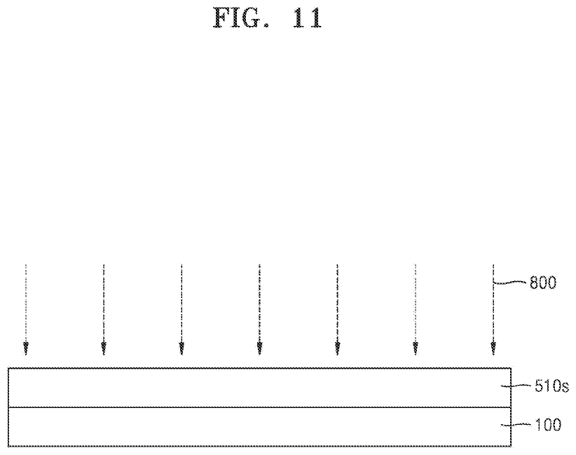

Referring to FIG. 11, pulse light 800 including a plurality of pulses may be irradiated onto the quantum dot-including material 510s. For example, the pulse light 800 may irradiate (may be irradiated onto) at least a portion of the quantum dot-including material 510s. At least a portion of the quantum dot-including material 510s irradiated with the pulse light 800 may be cured to form a color conversion layer 510.

The pulse light 800 may include ultraviolet light and visible light. For example, the wavelength range of the pulse light 800 may be about 250 nm to about 650 nm including ultraviolet light and visible light. In one or more embodiments, the wavelength range of the pulse light 800 may be about 250 nm to about 700 nm including ultraviolet light and visible light. In one or more embodiments, the wavelength range of the pulse light 800 may be about 250 nm to about 750 nm including ultraviolet light and visible light. Also, the wavelength range of the pulse light 800 may be about 250 nm to about 800 nm including ultraviolet light and visible light. However, the present disclosure is not limited thereto.

The radical photoinitiator such as UV-Irgacure (UV photoinitiator) included in the quantum dot-including material 510s may absorb UV (ultraviolet light). The radical photoinitiator such as UV-Irgacure (UV photoinitiator) having absorbed ultraviolet light may generate free radicals to trigger polymerization of the quantum dot-including material 510s.

The quantum dots of the quantum dot-including material 510s may absorb visible light in a particular band. For example, the quantum dots of the quantum dot-including material 510s may absorb light in one wavelength range of red, green, or blue. For example, the quantum dots of the quantum dot-including material 510s may absorb light in a wavelength range of about 440 nm to about 490 nm that is a wavelength range of blue light. The quantum dots of the quantum dot-including material 510s may absorb light in a wavelength range of about 490 nm to about 570 nm that is a wavelength range of green light. The quantum dots of the quantum dot-including material 510s may absorb light in a wavelength range of about 570 nm to about 585 nm that is a wavelength range of yellow light. The quantum dots of the quantum dot-including material 510s may absorb light in a wavelength range of about 620 nm to about 750 nm that is a wavelength range of red light. The quantum dots having absorbed visible light may transmit energy in the form of heat to the surroundings thereof. The quantum dot-including material 510s may be cured as the quantum dots having absorbed visible light transmit heat to the surroundings thereof.

As described above with reference to FIG. 9, if (e.g., when) the pulse light 800 irradiates the quantum dot-including material 510s, the curing rate of the quantum dot-including material 510s may be improved in a shorter time than if (e.g., when) light continuously irradiates the quantum dot-including material 510s. If (e.g., when) the pulse light 800 irradiates the quantum dot-including material 510s, the process efficiency may increase compared to the case where light continuously irradiates the quantum dot-including material 510s.

In one or more embodiments, the intensity of the pulse light 800 may be about 1 kW/cm² to about 50 kW/cm². If (e.g., when) the intensity of the pulse light 800 is less than 1 kW/cm², it may not be sufficient for polymerization and curing of the quantum-dot including material 510s. Also, if (e.g., when) the intensity of the pulse light 800 exceeds 50 kW/cm², the quantum-dot including material 510s may be damaged. Also, if (e.g., when) the intensity of the pulse light 800 exceeds 50 kW/cm², damage may be applied to the first substrate 100 or the intermediate layer 160 disposed under the quantum-dot including material 510s. The total energy of the pulse light 800 may be about 20 J to about 200 J. If (e.g., when) the total energy of the pulse light 800 is less than 20 J, it may not be sufficient for polymerization and curing of the quantum-dot including material 510s. Also, if (e.g., when) the total energy of the pulse light 800 exceeds 200 J, the quantum-dot including material 510s may be damaged. Also, if (e.g., when) the total energy of the pulse light 800 exceeds 200 J, damage may be applied to the first substrate 100 or the intermediate layer 160 disposed under the quantum-dot including material 510s. The duration of at least one pulse included in the pulse light 800 may be about 500 μs to about 5,000 μs. If (e.g., when) the duration of at least one pulse included in the pulse light 800 is less than 500 μs, the energy of one pulse should be high, and if (e.g., when) the pulse light with high energy irradiates for a short time, damage may be applied to the first substrate 100 or the intermediate layer 160 disposed under the quantum-dot including material 510s. If (e.g., when) the duration of at least one pulse included in the pulse light 800 exceeds 5,000 μs, the time required for the process may become similar and thus the process efficiency may not increase compared to the existing process of continuously irradiating light. Also, the duration of the pulse light 800 may increase and thus the temperature of the first substrate 100 may increase.

Also, in the related art, in order to cure the quantum dot-including material 510s, a vacuum chamber with nitrogen (N₂) removed therefrom is required. In one or more embodiments, because the heat generated by the quantum dots having absorbed visible light may remove oxygen (O₂), the quantum dot-including material may be cured even in the presence of air, not in a vacuum chamber.

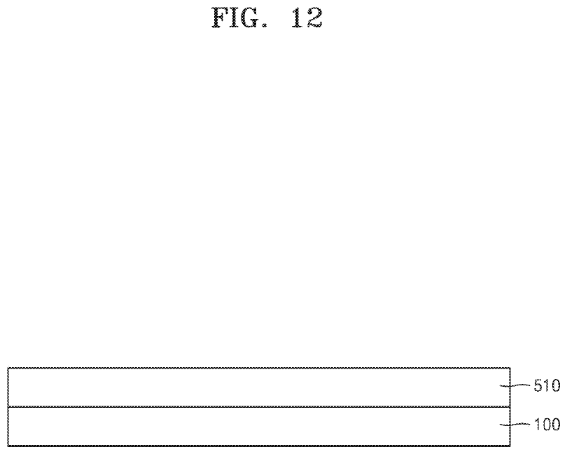

Referring to FIG. 12, at least a portion of the quantum dot-including material 510s irradiated with the pulse light 800 may be cured to form a color conversion layer 510. Also, in one or more embodiments, the quantum dot-including material 510s irradiated with the pulse light 800 may be cured to form an emission layer 162 including quantum dots. However, the present disclosure is not limited thereto.

In the related art, a substrate and a photoresist formed on the substrate are disposed in a curing machine, and then, the photoresist is cured to form a bank layer. If (e.g., when) the photoresist is cured by the curing machine, the temperature of the photoresist may increase to about 250° C. due to the pigment and/or dye, such as carbon black or dichroic dye, included in the photoresist. Because the photoresist is cured through the curing machine, only the temperature of the photoresist may not be locally increased and accordingly, the substrate and the intermediate layer disposed thereunder may be damaged.

In one or more embodiments, because at least a portion of the photoresist 540s may be irradiated with the pulse light 800 including visible light and ultraviolet light, and thus the temperature of the photoresist 540s may increase due to the heat transmitted to the surroundings thereof by the carbon black or dichroic dye of the photoresist 540s having absorbed visible light, the temperature of only at least a portion of the photoresist 540s irradiated with the pulse light 800 may increase locally and damage to the first substrate 100 and the intermediate layer 160 disposed under the photoresist 540s may be prevented or reduced. Also, if (e.g., when) the pulse light 800 irradiates, because the pulse light 800 irradiates the photoresist 540s for a short time, the time required for the process may decrease and thus the process efficiency may increase, compared to the case of curing the photoresist 540s by continuously irradiating the photoresist 540s with light. If (e.g., when) the pulse light 800 with high intensity irradiates the photoresist 540s, the pulse light 800 may reach the photoresist 540s adjacent to the first substrate 100, compared to the case where the photoresist 540s is cured through a curing machine. Thus, if (e.g., when) the photoresist 540s is cured by irradiating with the pulse light 800, the hardness of the first bank layer 540 may be improved and the inclination angle (taper angle) between the bank layers 540 and 640 and the first substrate 100 may be freely formed in a wide range.

According to embodiments described above, a method of manufacturing of a display apparatus with improved process efficiency may be implemented. However, the scope of the present disclosure is not limited to these effects.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A method of manufacturing a display apparatus, the method comprising:
supplying a substrate;
forming a photoresist on the substrate;
irradiating at least a portion of the photoresist with a pulse light comprising a plurality of pulses; and
forming a bank layer by curing at least the portion of the photoresist irradiated with the pulse light,
wherein a wavelength range of the pulse light is greater than or equal to about 250 nm and less than or equal to about 650 nm.

2. The method of claim 1, wherein an intensity of the pulse light is greater than or equal to about 1 kW/cm² and less than or equal to about 50 kW/cm².

3. The method of claim 1, wherein a total energy of the pulse light is about 20 J to about 200 J.

4. The method of claim 1, wherein a duration of at least one pulse of the plurality of pulses of the pulse light is greater than or equal to about 500 μs and less than or equal to about 5,000 μs.

5. The method of claim 1, wherein a curing rate of the bank layer is greater than or equal to about 80% and less than or equal to about 100%.

6. The method of claim 1, wherein a temperature of at least the portion of the photoresist irradiated with the pulse light is greater than or equal to about 100° C. and less than or equal to about 250° C.

7. The method of claim 1, wherein a temperature of the substrate is greater than or equal to about 20° C. and less than or equal to about 80° C. after irradiating the portion of the photoresist with the pulse light.

8. The method of claim 1, further comprising pre-curing the photoresist before the irradiating of the portion of the photoresist with the pulse light.

9. The method of claim 1, further comprising removing a portion of the photoresist not irradiated with the pulse light before the forming of the bank layer by curing at least the portion of the photoresist irradiated with the pulse light.

10. The method of claim 1, wherein the photoresist comprises a dye or a pigment.

11. The method of claim 10, wherein the photoresist comprises carbon black or dichroic dye.

12. The method of claim 1, wherein the photoresist comprises metal, dielectric, or oxide nanoparticles.

13. The method of claim 1, wherein the photoresist comprises a radical photoinitiator.

14. The method of claim 13, wherein the photoresist comprises an ultraviolet photoinitiator.

15. The method of claim 1, wherein the substrate comprises at least one selected from among silicon oxynitride (SiON), silicon nitride (SiNₓ), silicon oxide (SiOₓ), polyimide, and polyethylene terephthalate (PET).

16. A method of manufacturing a display apparatus, the method comprising:
supplying a substrate;
forming a quantum dot-comprising material on the substrate;
irradiating at least a portion of the quantum dot-comprising material with a pulse light comprising a plurality of pulses; and
forming a color conversion layer by curing at least the portion of the quantum dot-comprising material irradiated with the pulse light,
wherein the wavelength range of the pulse light is greater than or equal to about 250 nm and less than or equal to about 650 nm.

17. The method of claim 16, wherein an intensity of the pulse light is greater than or equal to about 1 kW/cm² and less than or equal to about 50 kW/cm².

18. The method of claim 16, wherein a total energy of the pulse light is greater than or equal to about 20 J and less than or equal to about 200 J.

19. The method of claim 16, wherein a duration of at least one pulse of the plurality of pulses of the pulse light is greater than or equal to about 500 μs and less than or equal to about 5,000 μs.

20. The method of claim 16, wherein the quantum dot-comprising material does not comprise a pigment or a dye.
